(19) United States
(12) Patent Application Publication
(10) Pub. No.: US 2021/0080518 A1
(43) Pub. Date: Mar. 18, 2021

(54) MAGNETIC SENSOR DEVICE

(71) Applicant: KABUSHIKI KAISHA TOKAI RIKA DENKI SEISAKUSHO, Aichi (JP)

(72) Inventor: Tadashi SHIBATA, Aichi (JP)

(73) Assignee: KABUSHIKI KAISHA TOKAI RIKA DENKI SEISAKUSHO, Aichi (JP)

(21) Appl. No.: 17/050,658

(22) PCT Filed: Jun. 6, 2019
(86) PCT No.: PCT/JP2019/022511

§ 371 Date: Oct. 26, 2020

(30) Foreign Application Priority Data
Jun. 11, 2018 (JP) 2018-111363

(51) Int. Cl. G01R 33/09; G01R 33/038

(52) U.S. Cl. CPC G01R 33/091; G01R 33/038

(57) ABSTRACT

A magnetic sensor device includes a first magnetic sensor including a ring-shaped first magnetosensitive part whose magnetoresistance value changes due to interaction with a radial magnetic field produced by a magnet, and a second magnetic sensor and a third magnetic sensor that are arranged based on an ideal trajectory of the magnet passing through the center of the first magnetic sensor, include a ring-shaped second magnetosensitive part and a ring-shaped third magnetosensitive part, respectively, and are arranged inside the first magnetic sensor so as to face each other without overlapping.

### CROSS-REFERENCES TO RELATED APPLICATIONS

The present patent application claims the priority of Japanese patent application No. 2018/111363 filed on Jun. 11, 2018, and the entire contents of Japanese patent application No. 2018/111363 are hereby incorporated by reference.

### TECHNICAL FIELD

The present invention relates to a magnetic sensor device.

### BACKGROUND ART

A non-contact switch is known, which is provided with a button arranged at a predetermined position on the housing, operated by external pressure and having a magnetic body at one end, and a magnetic field sensor element housed in the housing, facing the magnetic body and generating an induced voltage corresponding to a distance from the magnetic body (see, e.g., Patent Literature 1).

Unlike existing switches adapting a contact-type structure, this non-contact switch which realizes a contactless structure by using the magnetic field sensor element, etc., can have improved durability as compared to the existing switches and also can eliminate noise which could be generated at the time of operation of the switch. A magneto-resistive element, etc., is used as the magnetic field sensor element.

### CITATION LIST

### Patent Literature

Patent Literature 1: JP 2015-507871 A

### SUMMARY OF INVENTION

### Technical Problem

MR (Magneto Resistive) sensor having a circular magneto-resistive element is known as such a magnetic field sensor element. When a magnet generating a radial magnetic field is located at the center of the MR sensor, an angle formed between the magnetic field and the magneto-resistive element is a right angle. Therefore, the magnetoresistance value becomes smaller than when the magnet is located outside, and switching of the state such as ON and OFF can be detected. This MR sensor, however, has a problem that accuracy of state switching decreases when the position of the magnet varies.

It is an object of the invention to provide a magnetic sensor device which provides high switching accuracy.

### Solution to Problem

According to an embodiment of the invention, a magnetic sensor device comprises:
a first magnetic sensor comprising a ring-shaped first magnetosensitive part whose magnetoresistance value changes due to interaction with a radial magnetic field produced by a magnet; and
a second magnetic sensor and a third magnetic sensor that are arranged based on an ideal trajectory of the magnet passing through the center of the first magnetic sensor, comprise a ring-shaped second magnetosensitive part and a ring-shaped third magnetosensitive part, respectively, and are arranged inside the first magnetic sensor so as to face each other without overlapping.

### Advantageous Effects of Invention

According to an embodiment of the invention, it is possible to provide a magnetic sensor device which provides high switching accuracy.

### BRIEF DESCRIPTION OF DRAWINGS

FIG. 1A is an explanatory diagram illustrating a magnetic sensor device in an embodiment.

FIG. 1B is a block diagram illustrating the magnetic sensor device in the embodiment.

FIG. 2A is a graph showing a relation between the position of a magnet and the resistance value of a magnetic sensor unit including the magnetoresistance value in the magnetic sensor device of the embodiment and in a magnetic sensor device of Comparative Example.

FIG. 2B is an explanatory diagram illustrating the magnetic sensor device in a modification.

FIG. 3 is a flowchart showing an operation of the magnetic sensor device in the embodiment.

### DESCRIPTION OF EMBODIMENTS

### Summary of the Embodiment

A magnetic sensor device in an embodiment has a first magnetic sensor comprising a ring-shaped first magnetosensitive part whose magnetoresistance value changes due to interaction with a radial magnetic field produced by a magnet, and a second magnetic sensor and a third magnetic sensor that are arranged based on an ideal trajectory of the magnet passing through the center of the first magnetic sensor, comprise a ring-shaped second magnetosensitive part and a ring-shaped third magnetosensitive part, and are arranged inside the first magnetic sensor so as to face each other without overlapping.

This magnetic sensor device is configured such that, even when the amount of change in the magnetoresistance value of the first magnetic sensor decreases due to deviation of the magnet from the ideal trajectory, the decrease is compensated by the amount of change in the magnetoresistance values of the second magnetic sensor and the third magnetic sensor. Therefore, it is possible to provide higher switching accuracy as compared to when one ring-shaped magnetic sensor is arranged.

### EMBODIMENT

### (General Configuration of a Magnetic Sensor Device 1b)

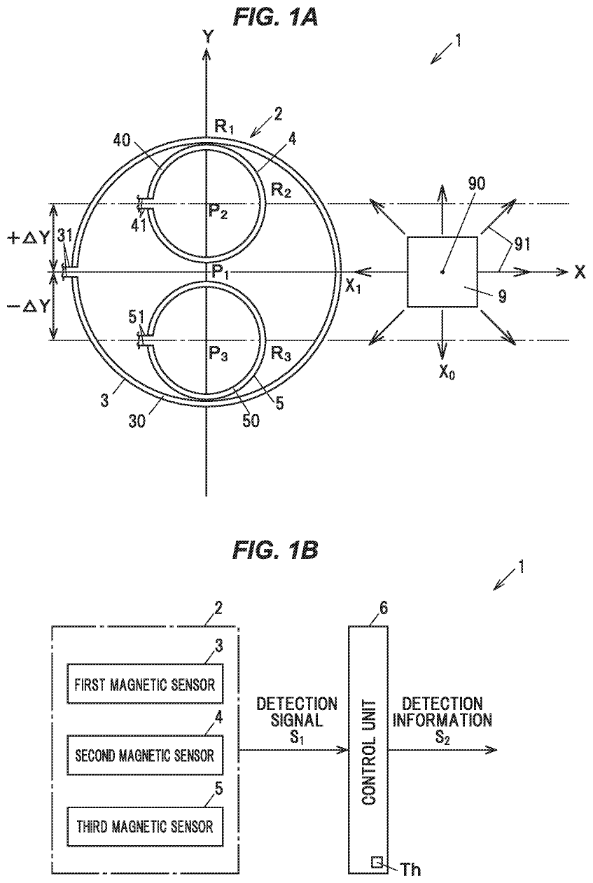

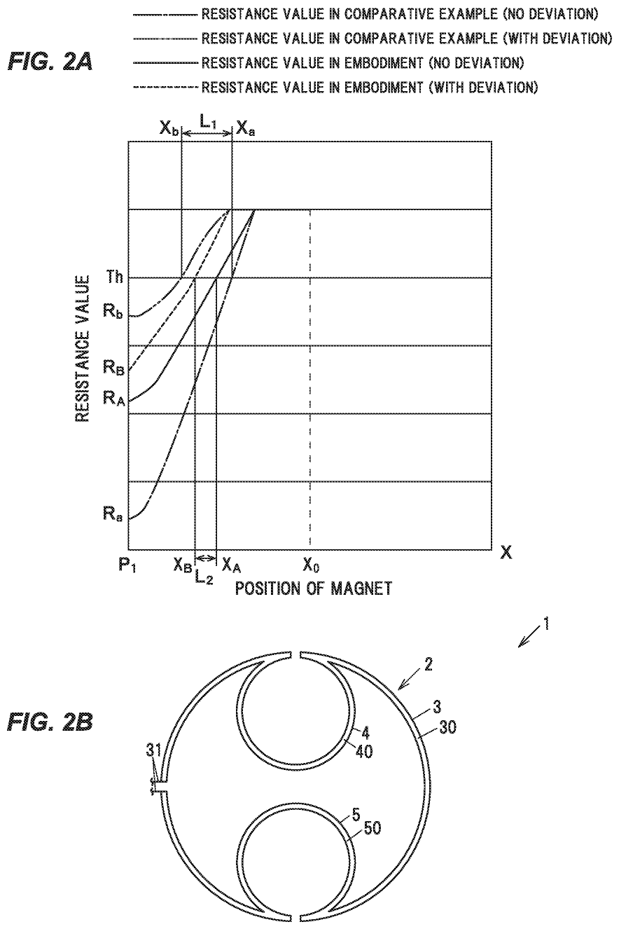

FIG. 1A is an explanatory diagram illustrating a magnetic sensor device in the embodiment and FIG. 1B is a block diagram illustrating the magnetic sensor device in the embodiment. FIG. 2A is a graph showing a relation between the position of the magnet and the resistance value of the magnetic sensor unit including the magnetoresistance value in the magnetic sensor device of the embodiment and in a magnetic sensor device of Comparative Example and FIG. 2B is an explanatory diagram illustrating the magnetic sensor device in a modification.

An XY-coordinate system with the origin at a center P₁ of a first magnetic sensor 3 is shown in FIG. 1A. In this XY-coordinate system, the horizontal axis is the x-axis and the vertical axis is the y-axis. In FIG. 2A, the resistance value with deviation in the embodiment is indicated by a dotted line, the resistance value with no deviation in the embodiment is indicated by a solid line, the resistance value with deviation in the Comparative Example is indicated by a phantom line, and the resistance value with no deviation in the Comparative Example is indicated by a dashed-dotted line. In FIG. 1B, flows of main signal and information are indicated by arrows.

A magnetic sensor device 1 detects, e.g., approach and separation of a magnet 9 to/from the magnetic sensor device 1. As an example, the magnetic sensor device 1 is used in a non-contact switch which detects ON and OFF, or in an electronic device which detects two states such as an operation device detecting whether or not an operation is performed on an operation part. The magnetic sensor device 1 in the present embodiment is used in a non-contact switch which determines approach of the magnet 9 as ON and separation as OFF, as an example.

The magnetic sensor device 1 has, e.g., a first magnetic sensor 3 having a ring-shaped first magnetosensitive part 30 having a magnetoresistance value which changes due to interaction with a radial magnetic field 91 produced by the magnet 9, and a second magnetic sensor 4 and a third magnetic sensor 5 which are arranged based on an ideal trajectory of the magnet 9 passing through the center of the first magnetic sensor 3, have a ring-shaped second magnetosensitive part 40 and a ring-shaped third magnetosensitive part 50, and are arranged inside the first magnetic sensor 3 so as to face each other without overlapping, as shown in FIG. 1A.

The second magnetic sensor 4 and the third magnetic sensor 5 are arranged so as to have centers at positions separated from the ideal trajectory of the magnet 9 by an acceptable amount of deviation of the magnet 9. The ideal trajectory here is the travel path of the magnet 9 when providing the largest amount of change in the magnetoresistance value of the first magnetic sensor 3 and is, e.g., the x-axis shown in FIG. 1A. That is, when a center 90 of the magnet 9 is arranged without deviation from the x-axis direction in the y-axis direction, the center 90 moves from an initial position X₀ to the center P₁ of a magnetic sensor unit 2 along the x-axis. Therefore, a trajectory of the center 90 of the magnet 9, when projected onto a plane in which the magnetic sensor unit 2 is placed, is a trajectory along the x-axis. The magnetic sensor unit 2 outputs a magnet detection signal for turning an intended switch or electronic device, etc., from OFF to ON or ON to OFF depending on a predetermined displacement of the magnet 9 on the trajectory. Here, the initial position X₀ mentioned above is a position at which the magnet 9 stands by in the ON- or OFF-state of the switch or electronic device, etc., and is ready for the predetermined displacement.

The second magnetic sensor 4 and the third magnetic sensor 5 are arranged so as to have a center P₂ and a center P₃ at positions separated from the center P₁ of the first magnetic sensor 3 by the acceptable amount in a direction orthogonal to the trajectory of the magnet 9.

The acceptable amount here is the maximum amount of deviation which is estimated at the time of design, as an example. The acceptable amount is, e.g., ±ΔY which are distances from the x-axis to two straight lines indicated by dashed-dotted lines in FIG. 1A.

The second magnetic sensor 4 has the center P₂ at a position separated from the x-axis by +ΔY. Meanwhile, the third magnetic sensor 5 has the center P₃ at a position separated from the x-axis by −ΔY. The center P₂ of the second magnetic sensor 4 and the center P₃ of the third magnetic sensor 5 do not necessarily need to be the maximum value of the deviation.

The magnetic sensor device 1 is configured such that, e.g., the first to third magnetic sensors 3 to 5 are connected in series, and a control unit 6 as a detection unit detecting the magnet based on the magnetoresistance values of the first to third magnetic sensors 3 to 5 is provided, as shown in FIG. 1B. In the following description, the first to third magnetic sensors 3 to 5 are connected in series and form the magnetic sensor unit 2.

### (Configuration of the Magnetic Sensor Unit 2)

The first to third magnetic sensors 3 to 5 are magneto-resistive elements of which magnetoresistance values change depending on the direction of the magnetic field 91. As shown in FIG. 1A, the first to third magnetic sensors 3 to 5 are partially cut out. One of a wiring 31, a wiring 41 and a wiring 51 is connected to each of the first to third magnetic sensors 3 to 5. The first to third magnetic sensors 3 to 5 are connected in series via the wirings 31 to 51. The positions of the cutouts on the first to third magnetic sensors 3 to 5 to be connected to the wirings can be freely set.

The first to third magnetosensitive parts 30 to 50 of the first to third magnetic sensors 3 to 5 have a ring shape. The first to third magnetosensitive parts 30 to 50 are formed as, e.g., thin alloy films consisting mainly of a ferromagnetic metal such as Ni or Fe.

Meanwhile, the wirings 31 to 51 are formed of, e.g., a metal material of which resistance value does not change with the change in the direction of the magnetic field 91, such as copper.

The second magnetic sensor 4 and the third magnetic sensor 5 are configured such that the second magnetosensitive part 40 and the third magnetosensitive part 50 have the same radius and the second magnetosensitive part 40 and the third magnetosensitive part 50 have the same resistance value including the magnetoresistance value. In addition, the second magnetosensitive part 40 and the third magnetosensitive part 50 are formed close to an inner circumference of the first magnetosensitive part 30 of the first magnetic sensor 3 to the extent that insulating properties are maintained. Thus, the radii of the second magnetosensitive part 40 and the third magnetosensitive part 50 are set based on the ON-OFF switching position, the widths of the magnetosensitive parts, and the centers P₂ and P₃ based on ±ΔX.

The magnetoresistance value R₁ of the first magnetic sensor 3 is preferably a value equal to the sum of the magnetoresistance value R₂ of the second magnetic sensor 4 and the magnetoresistance value R₃ of the third magnetic sensor 5 (R₁=R₂+R₃), as an example, from the viewpoint of correcting the amount of change in the magnetoresistance value R₁ caused by deviation. This is because the effect of the correction is small if the magnetoresistance values R₂ and R₃ are magnetoresistance values which are extremely smaller than the magnetoresistance value R₁. The equation mentioned above is also true for resistance values other than the magnetoresistance values. In other words, the resistance value of the first magnetic sensor 3 including the magnetoresistance value R₁ is a value equal to the sum of the resistance value of the second magnetic sensor 4 including the magnetoresistance value R₂ and the resistance value of the third magnetic sensor 5 including the magnetoresistance value R₃.

Alternatively, the magnetoresistance values R₁ to R₃ may be equal to each other, as a modification. In this case, the magnetoresistance values are adjusted by changing a material of the magnetosensitive parts and the widths of the magnetosensitive parts, etc.

The center P₂ of the second magnetic sensor 4 and the center P₃ of the third magnetic sensor 5 are located on, e.g., the y-axis in the same manner as the center P₁ of the first magnetic sensor 3 as shown in FIG. 1A, but it is not limited thereto. The centers P₂ and P₃ are moved, i.e., in the positive direction of the x-axis when moving the ON-OFF switching position toward the outside and are moved in the negative direction when moving the ON-OFF switching position toward the inside.

The magnetic sensor unit 2 outputs, e.g., a detection signal S₁, as shown in FIG. 1B. The detection signal S₁ is, e.g., a voltage signal.

### (Configuration of the Control Unit 6)

The control unit 6 is, e.g., a microcomputer composed of a CPU (Central Processing Unit) performing calculation and processing, etc., of the acquired data according to a stored program, and a RAM (Random Access Memory) and a ROM (Read Only Memory) which are semiconductor memories, etc. The ROM stores, e.g., a program for operation of the control unit 6, and a threshold value Th. The RAM is used as, e.g., a storage area for temporarily storing calculation results, etc.

The control unit 6 calculates the resistance value including the magnetoresistance value based on the detection signal S₁ acquired from the magnetic sensor unit 2 and a supplied current, and compares the resistance value with the threshold value Th. When the calculated resistance value is not more than the threshold value Th, the control unit 6 determines that it is switched from ON to OFF or OFF to ON.

In the present embodiment, as an example, it is OFF when the center 90 of the magnet 9 is located outside the magnetic sensor unit 2, and it is ON when located inside the magnetic sensor unit 2. This switching between ON and OFF occurs at, e.g., the x-coordinate X₁ which is an intersection between the outer circumference of the first magnetosensitive part 30 of the first magnetic sensor 3 and the x-axis as shown in FIG. 1A, but it is not limited thereto.

This ON-OFF switching position moves due to deviation of the magnet 9. Thus, switching between ON and OFF occurs within a range defined based on the switching position without deviation and the switching positions with ±ΔY since the magnetic field 91 at +ΔX and −ΔY is symmetric. Regarding this, the simulation result of the switching range in Comparative Example and the embodiment shown in FIG. 2A will be described below.

In Comparative Example, only the first magnetic sensor 3 is provided. Meanwhile, in the embodiment, the first to third magnetic sensors 3 to 5 are provided. The same magnet 9 is used in Comparative Example and the embodiment.

In Comparative Example, the switching start point, at which the resistance value becomes not more than the threshold value Th, is an x-coordinate Xₐ without deviation and an x-coordinate X_{b} with deviation, as shown in FIG. 2A. Therefore, switching between ON and OFF occurs at any point, corresponding to the deviation, within the switching range between the x-coordinate Xₐ and the x-coordinate X_{b}.

On the other hand, in the embodiment, the influence of deviation of the magnet 9 is smaller than Comparative Example, and the switching start point, at which the resistance value becomes not more than the threshold value Th, is an x-coordinate X_{A} without deviation and an x-coordinate X_{B} with deviation, as shown in FIG. 2A. Therefore, switching between ON and OFF occurs at any point, corresponding to the deviation, within the switching range between the x-coordinate X_{A} and the x-coordinate X_{B}.

In addition, a difference between a resistance value Rₐ without deviation from the center P₁ and a resistance value R_{b} with deviation in Comparative Example is much larger than a difference between a resistance value R_{A} without deviation and a resistance value R_{B} with deviation in the embodiment, as shown in FIG. 2A.

In addition, L₂<L₁ when a length between the x-coordinate Xₐ and the x-coordinate X_{b} in Comparative Example is defined as L₁ and a length between the x-coordinate X_{A} and the x-coordinate X_{B} in the embodiment is defined as L₂, as shown in FIG. 2A. For example, when it is set that switching between ON and OFF occurs, e.g., on the outer circumference of the first magnetic sensor 3 on the assumption of no deviation, i.e., occurs at the x-coordinate X₁, switching between ON and OFF in the embodiment occurs between the x-coordinate X₁ and somewhere in the range of the length L₂. Meanwhile, switching between ON and OFF in Comparative Example occurs between the x-coordinate X₁ and somewhere in the range of the length L₁. The result of the above comparison shows that the embodiment provides a narrower ON-OFF switching range and higher switching accuracy than Comparative Example.

Here, if a disturbance magnetic field acts on the magnetic sensor device 1, e.g., the disturbance magnetic field acts in the same direction on the first to third magnetic sensors 3 to 5. In this case, since the change in the magnetoresistance values of the first to third magnetic sensors 3 to 5 is small in the same manner as when the magnet 9 is located outside the magnetic sensor unit 2, the resistance value is higher than the threshold value Th, e.g., as shown in FIG. 2A.

Therefore, when the disturbance magnetic field is acing, the control unit 6 does not determine that the magnet 9 is at the ON position, hence, it is possible to prevent erroneous determination in which ON is determined due to the action of the disturbance magnetic field.

### (Configuration of the Magnet 9)

The magnet 9 has, e.g., a pillar shape, such as column or quadrangular prism, which generates the radial magnetic field 91, as shown in FIG. 1A. The magnet 9 in the present embodiment has, e.g., a quadrangular prism shape.

The magnet 9 is magnetized to have, e.g., an N-pole on the side of the magnetic sensor unit 2 located below, and an S-pole on the other side, as shown in FIG. 1A. Thus, the magnet 9 generates the radial magnetic field 91 toward the magnetic sensor unit 2, e.g., as shown in FIG. 1A. The magnetic poles of the magnet 9 may be located the other way round.

The magnet 9 is obtained by, e.g., shaping a permanent magnet such as alnico magnet, ferrite magnet or neodymium magnet into a desired shape, or by mixing a magnetic material based on ferrite, neodymium, samarium-cobalt or samarium-iron-nitrogen, etc., with a synthetic resin material and shaping into a desired shape. The magnet 9 in the present embodiment is a permanent magnet, as an example. Alternatively, the magnet 9 may be an electromagnet.

The magnet 9 is configured to, e.g., linearly move from the initial position X₀ to the center P₁ of the magnetic sensor unit 2, as shown in FIG. 1A.

The magnetic sensor device 1 as a modification is configured such that the first to third magnetosensitive parts 30 to 50 of the first to third magnetic sensors 3 to 5 are connected into one magnetosensitive part, e.g., as shown in FIG. 2B. In this magnetic sensor device 1, the second magnetic sensor 4 and the third magnetic sensor 5 are inscribed in the first magnetic sensor 3 in such a manner that the first to third magnetosensitive parts 30 to 50 are connected. Therefore, the magnetic sensor device 1 in the modification requires, e.g., only the wiring 31 as shown in FIG. 2B, hence, wiring is easy and the number of wirings is also reduced.

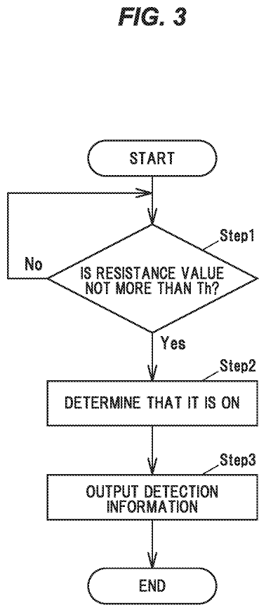

Next, an example of an operation of the magnetic sensor device 1 in the present embodiment will be described along with the flowchart in FIG. 3. In this example, an operation when switching from OFF to ON will be described.

### (Operation)

When the power is turned on, the control unit 6 of the magnetic sensor device 1 monitors the detection signal S₁. When it is “Yes” in Step 1, i.e., when the resistance value calculated based on the detection signal S₁ is not more than threshold value Th (Step 1: Yes), the control unit 6 determines that the state is switched from OFF to ON (Step 2).

Based on the determination result, the control unit 6 generates detection information S₂ indicating determination of “ON” and outputs it to a connected electronic device (Step 3).

### Effects of the Embodiment

The magnetic sensor device 1 in the present embodiment can provide high switching accuracy. In detail, the magnetic sensor device 1 is configured such that, even when the amount of change in the magnetoresistance value of the first magnetic sensor 3 decreases due to deviation of the magnet 9 from the ideal trajectory (the x-axis), the decrease is compensated by the amount of change in the magnetoresistance values of the second magnetic sensor 4 and the third magnetic sensor 5. Therefore, the switching range is narrower and it is thus possible to provide higher switching accuracy, as compared to when one ring-shaped magnetic sensor is arranged.

In the magnetic sensor device 1, the second magnetic sensor 4 and the third magnetic sensor 5 are arranged inside the first magnetic sensor 3. Therefore, the magnetic sensor unit 2 can be reduced in size as compared to when arranging outside the first magnetic sensor.

Even when the disturbance magnetic field is applied, it acts on the magnetic sensor unit 2 in the same direction similarly to when the magnet 9 is located outside the magnetic sensor unit 2, unlike when each magneto-resistive element is arranged rotationally symmetric. An erroneous determination causing switching from OFF to ON thus can be prevented and the magnetic sensor device 1 can thereby have a resistance to the disturbance magnetic field. Therefore, the magnetic sensor device 1 can be suitably used in an environment in which the disturbance magnetic field is likely to be generated, such as in vehicle.

Although some embodiment and modifications of the invention have been described, the embodiment and modifications are merely examples and the invention according to claims is not to be limited thereto. These new embodiment and modifications may be implemented in various other forms, and various omissions, substitutions and changes, etc., can be made without departing from the gist of the invention. In addition, all combinations of the features described in the embodiment and modifications are not necessary to solve the problem of the invention. Further, these embodiment and modifications are included within the scope and gist of the invention and also within the invention described in the claims and the range of equivalency.

### REFERENCE SIGNS LIST

1 MAGNETIC SENSOR DEVICE
3 FIRST MAGNETIC SENSOR
4 SECOND MAGNETIC SENSOR
5 THIRD MAGNETIC SENSOR
6 CONTROL UNIT
9 MAGNET
30 FIRST MAGNETOSENSITIVE PART
40 SECOND MAGNETOSENSITIVE PART
50 THIRD MAGNETOSENSITIVE PART

1. A magnetic sensor device, comprising:
a first magnetic sensor comprising a ring-shaped first magnetosensitive part whose magnetoresistance value changes due to interaction with a radial magnetic field produced by a magnet; and
a second magnetic sensor and a third magnetic sensor that are arranged based on an ideal trajectory of the magnet passing through the center of the first magnetic sensor, comprise a ring-shaped second magnetosensitive part and a ring-shaped third magnetosensitive part, respectively, and are arranged inside the first magnetic sensor so as to face each other without overlapping.

2. The magnetic sensor device according to claim 1, wherein the second magnetic sensor and the third magnetic sensor are arranged so as to have centers at positions separated from the ideal trajectory of the magnet by an acceptable amount of deviation of the magnet.

3. The magnetic sensor device according to claim 2, wherein the second magnetic sensor and the third magnetic sensor are arranged so as to have centers at positions separated from the center of the first magnetic sensor by the acceptable amount in a direction orthogonal to the trajectory of the magnet.

4. The magnetic sensor device according to claim 1, wherein the first to third magnetosensitive parts of the first to third magnetic sensors comprise thin alloy films that comprise mainly a ferromagnetic metal comprising Ni or Fe.

5. The magnetic sensor device according to claim 1, wherein the second magnetic sensor and the third magnetic sensor are configured such that the second magnetosensitive part and the third magnetosensitive part have the same radius and the same resistance value including the magnetoresistance value.

6. The magnetic sensor device according to claim 1, wherein the first magnetic sensor has the magnetoresistance value equal to the sum of the magnetoresistance value of the second magnetic sensor and the magnetoresistance value of the third magnetic sensor.

7. The magnetic sensor device according to claim 1, wherein the second magnetic sensor and the third magnetic sensor are formed close to an inner circumference of the first magnetosensitive part of the first magnetic sensor to the extent that insulating properties are maintained.

8. The magnetic sensor device according to claim 1, wherein the first to third magnetosensitive parts of the first to third magnetic sensors are connected into one magnetosensitive part.

9. The magnetic sensor device according to claim 1, wherein the first to third magnetic sensors are connected in series, and a detection unit detecting the magnet based on the magnetoresistance values of the first to third magnetic sensors is provided.

10. The magnetic sensor device according to claim 9, wherein the detection unit calculates a resistance value including the magnetoresistance value based on a detection signal, that is based on voltage output from the first to third magnetic sensors, and a current supplied to the first to third magnetic sensors, and detects the magnet by comparing the detection signal with a threshold value.
